(19) United States
(12) Patent Application Publication
(10) Pub. No.: US 2008/0088331 A1
(43) Pub. Date: Apr. 17, 2008

(54) Socket for test

(75) Inventor: Takuto Yoshida, Tokyo (JP)

Correspondence Address: MORGAN LEWIS & BOCKIUS LLP, 1111 PENNSYLVANIA AVENUE NW, WASHINGTON, DC, 20004, US

(73) Assignee: Yokowo Co., Ltd.

(21) Appl. No.: 11/898,311

(22) Filed: Sep. 11, 2007

(30) Foreign Application Priority Data
Sep. 12, 2006 (JP) P2006-246696

(51) Int. Cl. G01R 1/04; G01R 31/26

(52) U.S. Cl. 324/761; 324/754

(57) ABSTRACT

A socket for test includes: a support block, having a first face and a second face different from the first face, and formed with through holes; probes, provided in the through holes, and electrically connected to terminals of a device to be tested provided on a side of the first face and to terminals connected to a testing apparatus provided on a side of the second face, the probes including a first probe for grounding and a second probe different from the first probe; and a first plate member, formed with a first hole corresponding to the first probe and having a smaller diameter than a diameter of the first probe, slots radially extended from the first hole, and a second hole corresponding to the second probe and having a larger diameter than a diameter of the second probe, the first plate member being in electrical contact with the support block.

### BACKGROUND OF THE INVENTION

The present invention relates to a socket for test which interconnects electrode terminals (lead terminals) of a device to be tested and wiring terminals to be connected to a testing apparatus by means of probes which are supported by a metal block, for the purpose of testing electrical performance of the device to be tested such as an IC, before the device is actually assembled into a circuit. More particularly, the invention relates to the socket for test having improved contact structure in a probe for grounding, which is one of the probes, by which structure the probe for grounding can be easily assembled, while it is in reliable electrical contact with the metal block.

Test for testing performance of a device (an object to be tested) such as a semiconductor wafer, an IC or a module, by inputting an electric signal to the device, has been generally conducted. In case of conducting such test of electrical performance of the device, there has been employed a socket for test such as an IC socket which is provided with probes for interconnecting wiring terminals on a wiring board on which ends of leads to be connected to a testing apparatus are collected with electrode terminals (lead terminals) of the device. This socket for test is formed of metal or the like, for example, as shown in FIG. 7A, and the test is conducted by forming through holes in a metal block 92 for supporting probes 91, by inserting the probes 91 for signals, for power supply, and for grounding into the through holes, and by electrically connecting the electrode terminals (the lead terminals) of the device to be tested (not shown) which is provided on one face of the socket (an upper side in the drawing) to the wiring terminals of the wiring board (not shown) which is provided on the other face of the socket (a lower side in the drawing). A device guide 94 for positioning the device to be tested is provided on an outer face of this metal block 92 at a side where the device to be tested is mounted, integrally with the metal block 92 or formed as a separate component to be fixed by means of screws or the like which are not shown (for example, refer to JP-A-2004-170182). In FIG. 7A, reference numeral 93 designates fixing plates for fixing the probes 91 so as not to escape, and 96 designates positioning pins for positioning the socket for test with respect to the wiring board.

The reason why metal is used for the block for supporting the probes 91 is because the metal block prevents noises from entering into the electrode terminal for signals by way of the probe 91, in case where the device to be tested is a device for high frequency and high speed (high frequency in analogue form is referred to as the high frequency, while very short pulse width and short pulse interval in digital form are referred to as the high speed, both of which are hereinafter referred to as an RF) In order to further enhance RF performance, it is necessary to form the probe 91SIG for signals in a coaxial structure, and to reliably connect the probe 91GND for grounding to the ground in vicinity of the probe 91SIG for signals. For this purpose, as shown in FIG. 7B which is an enlarged sectional explanatory view of an area surrounding the probe 91SIG for signals, the probe 91GND for grounding, and the probe 91POW for power supply, the probe 91SIG for signals is formed in a coaxial structure in which the probe is a center conductor, an inner wall of the through hole in the metal block 92 is an external conductor, and a space between them is a dielectric substance. An outer diameter d of the probe 91SIG and an inner diameter D of the through hole are so set as to make a determined impedance. By constructing the probe 91SIG for signals in this manner, dielectric constant becomes 1, because a hollow space is formed between the center conductor and the external conductor, and the coaxial structure of the determined impedance can be obtained even at a narrow pitch, even in case where an interval between the electrode terminals becomes very small due to recent stream of downsizing and high density of the device. The probe 91GND for grounding is inserted into the through hole in the metal block 92 interposing a bell-shaped metal tube 97 having slots, for example, so that the probe can be reliably brought into contact with the metal block 92. The probe 91POW for power supply is inserted into the through hole in the metal block 92 interposing an insulating tube 98 so as not to get in touch with the metal block 92.

As described above, the socket for test for testing the RF device is formed by supporting the probes in the through holes in the metal block. In order to form the coaxial structure by combination of the probe for signals and the metal block, reliable electrical connection must be established between the probe for grounding and the metal block which serves as the ground. Therefore, the metal tube 97 is interposed between the probe 91GND for grounding and the metal block 92 for establishing the electrical connection. However, due to the recent stream of downsizing and high density of the electronic device, the pitch of the power supply terminals, that is, the pitch of the probes 91 has become very small up to usually 0.5 mm, or about 0.4 mm or less. Consequently, even in case where the pitch is 0.5 mm, an outer diameter of the probe 91GND for grounding is 0.3 mm, and an inner diameter of the through hole is 0.43 mm at the smallest. The metal tube 97 to be inserted between them is also very thin having a wall thickness of about 0.03 mm and very small having an outer diameter of about 0.43 mm. Therefore, it is difficult to manufacture the metal tube 97 in an optimal shape with high yield, even with such precision as having tolerance of ±0.01 mm. Further, since the metal tube 97 has the bell-shape, the metal tube 97 can be removed only from the opposite side, once it has been inserted into the through hole in the metal block 2, and there has been a problem that it takes a number of manufacturing steps and an increase of cost to interpose the metal tube 97.

### SUMMARY

It is therefore an object of the invention to provide a socket for test which is so constructed that electrical connection can be reliably obtained between a probe for grounding and a metal block, while respective probes are supported by the metal block, and that the socket can be easily manufactured employing low-cost components.

In order to achieve the object, according to the invention, there is provided a socket for test, comprising:

a support block, having a first face and a second face different from the first face, and formed with a plurality of through holes;

a plurality of probes, provided in the through holes, and electrically connected to terminals of a device to be tested which is provided on a side of the first face and to terminals connected to a testing apparatus which is provided on a side of the second face, the probes including a first probe for grounding and a second probe different from the first probe; and

a first plate member, formed with a first hole corresponding to the first probe and having a smaller diameter than a diameter of the first probe, slots radially extended from the first hole, and a second hole corresponding to the second probe and having a larger diameter than a diameter of the second probe, the first plate member being in electrical contact with the support block.

The support block may be comprised of metal.

The each of the probes may include a spring member. One end of each probe may be projected to at least the side of the first face of the support block.

The socket further includes a second plate member, provided on at least one of the first face and the second face of the support block, and comprised of one of insulating material and metallic material.

The first plate member may be arranged between the second plate member and the support block.

The first plate member may include a metal plate having a thickness of 0.02 mm to 0.05 mm.

The number of the slots may be three to sixteen.

### BRIEF DESCRIPTION OF THE DRAWINGS

FIGS. 1A and 1B are explanatory views showing a structure of the socket for test in an embodiment according to the invention.

FIGS. 2A, 2B, and 2C are an explanatory plan view showing a part of a ground plate in FIGS. 1A and 1B, an explanatory plan view showing a part of a metal block where a fixing plate and the ground plate are omitted, and an explanatory perspective view showing a part of the metal block provided with the ground plate, respectively.

FIG. 3 is a view showing a structure of a contact probe which is an example of probes as shown in FIGS. 1A and 1B.

FIGS. 4A, 4B, and 4C are views for explaining a manner of assembling the ground plate.

FIG. 5 is an explanatory sectional view showing a modification of the socket for test as shown in FIGS. 1A and 1B.

FIG. 6 is an explanatory sectional view showing another modification of the socket for test as shown in FIGS. 1A and 1B.

FIGS. 7A and 7B are views showing an example of the socket for test in the related art.

### DETAIL DESCRIPTION OF PREFERRED EMBODIMENTS

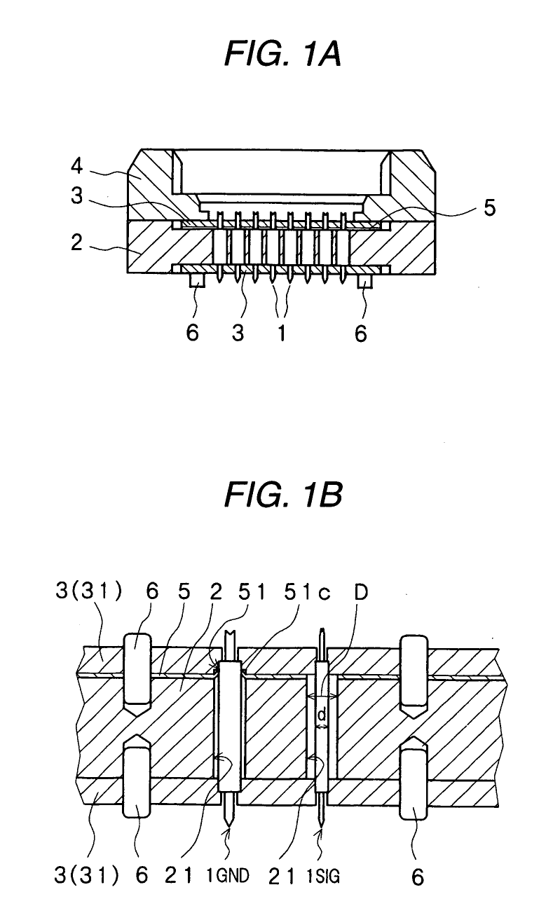

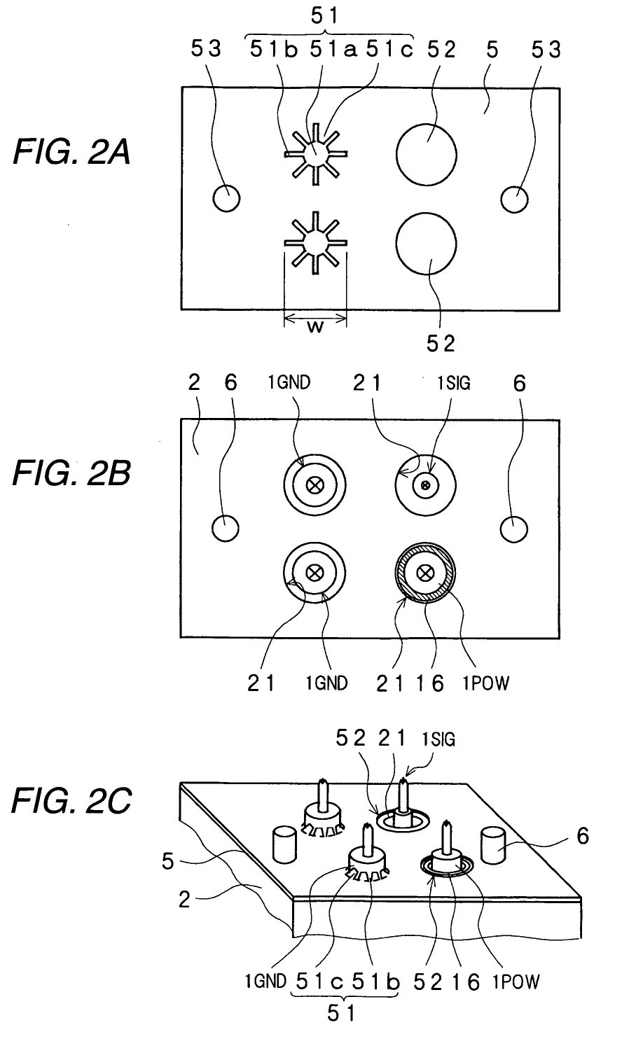

Now, referring to the drawings, the socket for test according to the invention will be described. In FIGS. 1A and 1B, there are shown a sectional view for explaining the socket for test in an embodiment according to the invention, and an enlarged sectional view for explaining a part of the same. In FIGS. 2A to 2C, there are shown a plan view for explaining a part of a ground plate, and a plan view for explaining a part of a metal block in which probes 1 are inserted, and a perspective view for explaining a part of the metal block 2 in a state where the ground plate 5 is mounted on a surface of the metal block (in a state where a fixing plate 3 is omitted).

Herein, the probe means a connecting pin which interconnects a wiring terminal on a wiring board with an electrode terminal (a lead terminal) of a device to be tested, including both a contact probe of a type that a distal end of the connecting pin is movable, and a pin having a fixed length but not movable. The contact probe means a probe which is so constructed that a distal end of a lead wire (a plunger) is movable and can be reliably kept in contact with the lead terminal or the like of the device to be tested. This can be realized by such a structure that the lead wire is provided via a spring inside a metal pipe, for example, and one end of the plunger is projected from the metal pipe, while the other end is formed so as not to escape from the metal pipe, whereby the plunger is retracted into an end part of the metal pipe by pushing the one end of the plunger, and the plunger is projected from the metal pipe with a spring force by releasing an external force.

The socket for test according to the invention has such a structure, as shown in FIGS. 1A and 1B for example, that the metal block 2 is formed with a plurality of through holes 21 for supporting the probes 1, and a probe 1SIG for signals, a probe 1POW for power supply (not shown in FIGS. 1A and 1B) and a probe 1GND for grounding are respectively held in the through holes 21, whereby electrode terminals of the device to be tested (not shown) which is provided on one face side of the metal block 2 are electrically connected to wiring terminals connected to a testing apparatus which is provided on the other face side thereof. In FIGS. 2A to 2C, two pieces of the probe 1GND for grounding, each of which is a part of the socket for test according to the invention, and one each of the probes 1SIG, 1POW for signals and for power supply are schematically shown (intervals between the holes are not accurate). The invention is characterized in that the ground plate 5 which is provided with relief holes 52 corresponding to positions of the probe 1SIG for signals and the probe 1POW for power supply and having such a size as not getting in touch with the probes 1, slotted holes 51 corresponding to positions of the probes 1GND for grounding each having a through hole 51a of a smaller size than a size of the probe 1GND for grounding and slots 51b radially extended from the through hole 51a, and positioning holes 53 is provided so as to be electrically connected to the metal block 2.

In case where pitch of the probes 1 is about 0.3 to 1 mm, for example, a metal plate having resilience such as a phosphor bronze plate or a stainless steel plate having a thickness of about 0.02 to 0.05 mm which is plated with gold on a first plating of nickel can be used as the ground plate 5. This is for the purpose of reliably obtaining electrical contact, by inserting the probe 1GND for grounding into the slotted hole 51, as described below. As shown in FIG. 2A, this ground plate 5 is formed with the holes corresponding to the positions of the respective probes 1 provided in the metal block 2, namely, the slotted holes 51 at the positions of the probes 1GND for grounding, the relief holes 52 at the positions of the probe 1SIG for signals and the probe 1POW for power supply, each having such a size as not getting in touch with the probes 1, and the positioning holes 53 at the positions where positioning pins 6 for positioning the ground plate 5 with respect to the metal block 2 are inserted.

As shown in FIG. 2A, the slotted hole 51 includes the through hole 51a, the slots 51b radially extended from the through hole 51a, and small pieces 51c interposed between the slots 51b. In the embodiment as shown in FIGS. 2A to 2C, the pitch of the probes 1 is 0.5 mm, and the probes having an outer diameter of 0.3 mm are used as the probe 1GND for grounding and the probe 1POW for power supply. In this case, a diameter of the through hole 51a is about 0.2 mm, a length of the slot 51b is about 0.1 mm, and a length w from an end of one of the slot 51b to an end of the opposite slot 51b is about 0.4 mm. Although the holes are shown in FIGS. 2A to 2C having larger intervals between them than in an actual case, the relief hole 52 for the probe 1SIG for signals or the probe 1POW for power supply usually has a diameter of about 0.42 mm. Therefore, in case where the length of the slot 51b is increased more, the relief hole 52 is likely to communicate with the adjacent relief hole 52 for the probe 1SIG for signals or the probe 1POW for power supply, or the slots 51b of the adjacent probe 1GND for grounding. In view of the above, the length of the slot 51b is set to be about 0.1 mm to the limit. The number of the slots 51b is eight in this embodiment. The slots 51b can be formed at the same time with the other through holes 51a and the relief holes 52 by punching, or can be formed one by one by laser beam work.

The number of the slots 51b is set depending on the pitch of the probes 1 and so on, so that optimal load may be exerted on the probe 1GND for grounding. Specifically, in case where the pitch of the probes 1 is larger than 0.5 mm, the length of the slots 51b can be increased, and hence, the number of the slots 51b can be reduced. In case where the slots 51b have a sufficient length, the small pieces 51c interposed between the slots 51b can be easily bent even though they have a large width, and therefore, it is possible to bring the small pieces 51c into contact with the probe 1GND for grounding with strong resiliency, without deforming the probe 1GND for grounding by imposing too much load. Alternatively, in case where the pitch is large, and the thick probe 1GND for grounding having a diameter larger than 0.3 mm can be used, the probe can bear a larger load. In this case, it is possible to obtain reliable electrical contact without deforming the probe 1GND for grounding, even though the number of the slots 51b is reduced and the width of the small pieces 51c is made larger. For this reason, in such cases, it is possible to obtain the contact with strong resiliency without deforming the probe 1GND for grounding, even though the number of the slots 51b is only three to five. On the other hand, in case where only the slots 51b having the length of less than 0.1 mm can be formed, as described above, it would be preferable that the number of the slots 51b is increased to 10 to 16, so that the electrical contact can be obtained with a large number of the small pieces 51c, though the resiliency becomes rather weak. For this reason, the number of the slots 51b is set depending on the pitch and the size of the probe 1 so that the optimal load may be exerted on the probe 1.

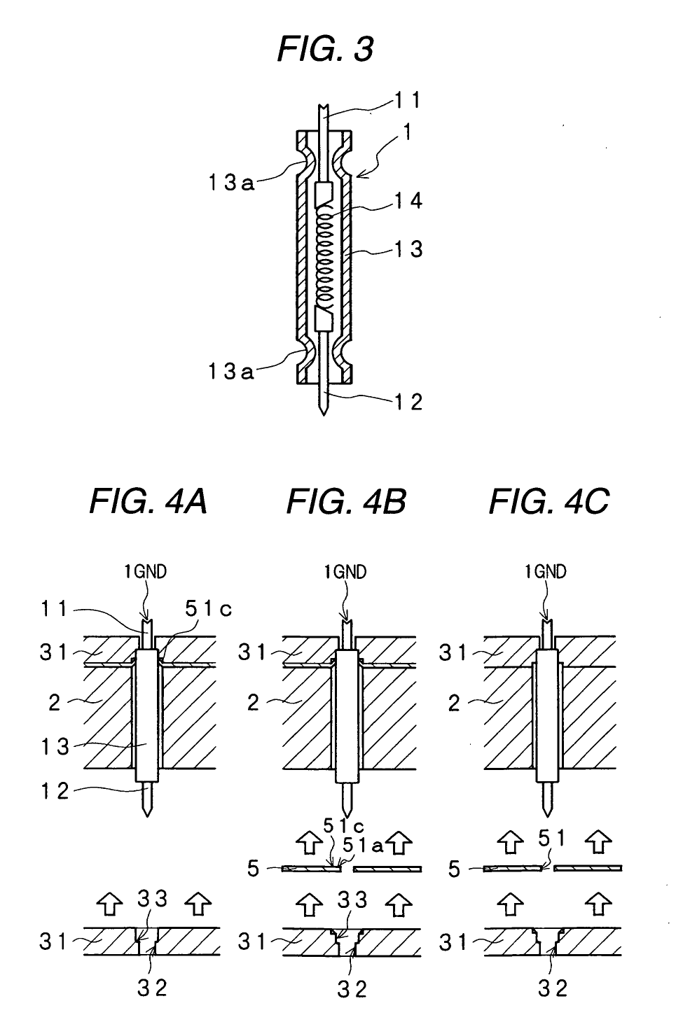

The other probes 1 and the metal block 2 can be substantially the same as the probes and the metal block in the related art. Specifically, as the probe 1, there is employed the contact probe of the type that the plunger (the lead wire) at the distal end is provided so as to be movable by the spring, so that the reliable contact with the device to be tested and the wiring board can be obtained, in the embodiment as shown in FIGS. 1A and 1B. However, the probe is not necessarily limited to this type having the movable pin. As shown in a sectional explanatory view of the embodiment in FIG. 3, the contact probe 1 as shown in FIGS. 1A and 1B has such a structure that a spring 14 and one ends of plungers 11, 12 are contained in a metal pipe 13, and the plungers 11, 12 are held so as not to escape from the metal pipe 13 by neck portions 13a which are formed in the metal pipe 13, and urged outward by the spring 14. By pressing tip ends of the plungers 11, 12, the spring 14 is contracted to push the tip ends into the metal pipe 13, and while no force is applied, the tip ends of the plungers 11, 12 are projected by about 1 mm, for example. Moreover, the tip end of the plunger 11 to be brought into contact with the electrode terminal of the device to be tested had better be split in four as shown in FIGS. 1A and 1B, for enabling the tip end to be reliably contacted.

Although the plungers 11, 12 are provided at both ends of the contact probe in the embodiment as shown in FIGS. 1A, 1B and FIG. 3, it would be sufficient that the plunger 11 is provided on at least one side of the contact probe which comes into contact with the device to be tested. For information, the metal pipe 13 has a length of about a few millimeters and may be formed of nickel silver (an alloy of copper, nickel and zinc), for example. As the plungers 11, 12, linear material having a diameter of about 0.1 mm and formed of SK material or beryllium copper may be used. The spring 14 may be formed of a piano wire or the like. The contact probes 1 have substantially the same structure irrespective of their objects for use, namely, for signals, for power supply, and for grounding. However, the contact probe 1SIG for high frequency and high speed signals is formed in a coaxial structure having this contact probe 1SIG as an inner conductor, as described below. In case where the pitch of the probes 1 is 0.5 mm as described above, the contact probe having an outer diameter of about 0.2 mm is used.

The metal block 2 is intended to hold the probe 1SIG for signals, the probe 1POW for power supply, and so on, and a metal plate formed of aluminum or brass, for example, can be used. It is possible to form the coaxial structure including the inner wall of the through hole 21 into which the contact probe 1SIG for signals is inserted, as the external conductor, and the contact probe 1SIG for signals, as the center conductor. The metal block 2 is formed with the through holes into which the aforesaid probes 1 are inserted. In case of the probe 1SIG for high frequency and high speed signals, the inner diameter D of the through hole 21 in the metal block 2 and the outer diameter d of the probe 1SIG for signals are set so as to satisfy the following formula (I) and so as to obtain the coaxial structure having a determined impedance Z₀. In the formula (I), ∈ᵣ is a dielectric constant of the dielectric substance between the center conductor and the external conductor. According to the structure as shown in FIGS. 1A and 1B, because a space is formed between the probe 1SIG for signals as the center conductor and the through hole 21 of the metal block 2 as the external conductor, the dielectric constant ∈ᵣ becomes 1. In this manner, it is possible to cope with the narrow pitch of the probes 1.

$$\begin{matrix}[ Formula 1 ] & \\ {z}_{0} = \frac{60}{\sqrt{{ɛ}_{r}}} {log}_{e} \frac{D}{d} & ( 1 )\end{matrix}$$

However, such relation of impedance does not exist in the probe 1POW for power supply, and the probe 1POW for power supply is covered with an insulating tube 16 (See FIG. 2B) having such a thickness that the probe may not make a short circuit with the metal block 2. Moreover, there is no problem even though the probe 1GND for grounding gets in touch with the inner wall of the through hole 21, and the through hole 21 into which the probe 1GND can be easily inserted is formed in the metal block 2. In the embodiment as shown in FIGS. 2A to 2C, all the through holes 21 for the probes 1 are formed having a diameter of about 0.4 mm. Although thickness and dimension of the metal block 2 may vary depending on the device to be tested, the metal block 2 is usually formed having a thickness of about 3 to 8 mm, and an area of 30 to 50 mm square.

In the embodiment as shown in FIGS. 1A and 1B, the fixing plate 3 includes an insulating board 31 which is provided on both faces of the metal block 2 and formed with through holes 32 and dented parts 33 (See FIGS. 4A to 4C) at positions corresponding to the through holes 21 in the metal block 2. The insulating board 31 is in a form of a plate having a thickness of about 0.6 mm and formed of resin, for example. As shown in FIGS. 4A to 4C, the insulating board 31 is provided with the through holes 32 through which the plungers 11, 12 can pass, corresponding to the positions of the contact probes 1, and the dented parts 33 which are formed concentrically with the through holes 32. The insulating board 31 is fixed at shoulder parts of the probes 1, that is, end parts of the metal pipes 13 in such a manner that the probes 1 may not escape. In the embodiment as shown in FIGS. 1A and 1B, by employing the insulating board 31 formed of resin such as polyether imide (PEI), the dented parts 33 and the through holes 32 can be more easily formed with precise dimensions by resin molding, even in case where a number of the probes 1 are arranged in parallel at a narrow pitch. Moreover, the above described resin has a large mechanical strength, and in case where the insulating board 31 is formed having the above described thickness, the contact probes of several hundreds or more can be very stably fixed, without occurring deflection. However, any other material can be also employed, provided that the material is electrically insulating and has a large mechanical strength, even though thin. In the embodiment as shown in FIGS. 1A and 1B, the probes at the side opposed to the wiring board (the lower side in the drawing) are also fixed by the fixing plate 3 (the insulating board 31) having substantially the same structure, so that the probes 1 may not escape to either side. This insulating board 31 is fixed to the metal block 2 by means of screws or the like which are not shown.

The insulating boards 31 provided on the both faces of the metal block 2 need not have necessarily the same thickness, but can be freely selected. In case where the plungers 11, 12 are projected from both sides of the probe 1, the dented parts 33 having substantially the same shape are formed. Moreover, on the side in contact with the wiring board which is connected to the testing apparatus, the same wiring board can be used, even though the type of the device to be tested is different. In case where the number of times when the probe is used is expected to be smaller as compared with the life of the probe 1, it is possible to fix one end part of the probe 1 to the wiring board by soldering or so, and it is unnecessary to form the plunger 12 at the one end of the contact probe 1 at the side connected to the wiring board. Alternatively, it is possible to fix the probe 1 by forming a dented part in the metal block 2, without providing the insulating board 31, at the one face side of the metal block 2, as described below (See FIG. 6). When the device to be tested which is not shown is set on the testing apparatus, the plunger 11 of the contact probe 1 is connected to the electrode terminal of the device to be tested, while being merged to a surface of the insulating board 31. The plunger 12 at the lower side is put on the wiring terminal on the wiring board which is connected to the testing apparatus which is not shown, thereby to be connected to the wiring terminal while it is retracted up to an exposed face of the insulating board 31 at the lower side.

An example where the probe 1GND for grounding, the probe 1SIG for signals, and the probe 1POW for power supply as described above are disposed in the through holes in the metal block 2 is shown in a plan view in FIG. 2B. In FIG. 1B, and FIGS. 2A to 2C, the positioning pins 6 are shown close to each other for convenience of explanation. However, actually, the positioning pins 6 are formed around the respective probes 1, as shown in FIG. 1A. FIG. 2C is an explanatory perspective view showing a state where the ground plate 5 is attached to the surface of the metal block 2 (On occasion of actually assembling, the socket in FIGS. 1A and 1B is turned upside down, and the ground plate is superposed on the insulating board 31 at the side opposed to the device to be tested, by positioning it by means of the positioning pins 6. Thereafter, the metal block 2 is superposed thereon by positioning it in the same manner, and the respective probes 1 are inserted, whereby the probe 1GND for grounding is inserted into the slotted hole 51 in the ground plate 5). FIG. 2C is a view showing the metal block 2 and the ground plate 5 in thus assembled state, omitting the insulating board 31. As shown in FIG. 2C, the probe 1GND for grounding is brought into contact with the ground plate 5 by spring force of the small pieces 51c of the ground plate 5, when they are pushed up. On the other hand, the probe 1SIG for signals and the probe 1POW for power supply are located in the center parts of the respective relief holes 52 which are slightly larger than the through holes 21 in the metal block 2, and will never come into contact with the ground plate 5.

Referring to FIG. 4A, a process for assembling the socket for test having the structure in which the ground plate 5 is brought into contact with the probe 1GND for grounding, by clamping the ground plate 5 between the metal block 2 and the insulating board 31 will be described. Although FIGS. 4A to 4C are drawn in alignment with FIGS. 1A and 1B in a vertical direction, the socket is turned upside down, when it is actually assembled. The ground plate 5 is superposed on the insulating board 31 at the upper side, by positioning it by means of the positioning pins 6, and the metal block 2 is superposed thereon by positioning. Then, the respective probes 1 are inserted into the through holes in the metal block 2. On occasion of inserting the probe 1GND for grounding, the probe 1GND for grounding is unable to be inserted, because the through hole 51a of the slotted hole 51 in the ground plate 5 has a smaller diameter than the outer diameter of the probe 1GND for grounding. However, by pushing the probe 1GND for grounding while exerting a load, the small pieces 51c of the ground plate 5 are bent and pushed in, until the shoulder part of the probe 1GND for grounding, that is, the end of the metal pipe 13 is butted against a stepped part of the dented part 33 of the insulating board 31, while the small pieces 51c are kept in contact with the probe 1GND for grounding, whereby the plunger 11 of the probe 1 is projected from the surface of the insulating board 31 through the through hole 32. Since a relief part for the small pieces 51c which have been bent is formed in the dented part 33 of the insulating board 31, the small pieces 51c are bent while tightly contacted with the probe 1GND for grounding, as shown in FIG. 1B. This state is shown at the upper side in FIG. 4A. Then, the insulating board 31 at the lower side is inserted by positioning it with the positioning pins which are not shown, whereby the respective probes 1 are fixed by the insulating boards 31 from both sides to be held inside the through holes in the metal block 2. The insulating board 31 is fixed to the metal block 2 with small screws or the like which are not shown, whereby the ground plate 5 is also firmly brought into electrical contact with the metal block 2. As the results, the socket for test having the structure as shown in FIGS. 1A and 1B can be obtained.

In order to test electrical performance of the device to be tested employing the socket for test having this structure, the socket for test is arranged so that the distal ends of the probes 1 may be in alignment with the wiring terminals on the wiring board (not shown) which is connected to the testing apparatus at the lower side in the drawing (Actually, by positioning the socket by means of the positioning pins 6), and the IC or the like which is the device to be tested is set inside the socket, along the device guide 4 of the socket. The device to be tested is positioned by means of this device guide 4, and the electrode terminals of the device to be tested are electrically connected to the respective probes 1 provided in the metal block 2, that is, the wiring terminals of the wiring board which is not shown. Then, by inputting determined electric voltage or the like from the testing apparatus which is not shown, test of the performance of the device to be tested will be conducted.

According to the socket for test of the invention, only because the ground plate provided with the slotted holes 51, the relief holes 52 and the positioning holes 53 as described above are interposed between the metal block 2 and the insulating board 31, it is possible to bring the ground plate into electrical contact with all the probes 1GND for grounding provided in the metal block 2. Therefore, one sheet of the ground plate 5 would be sufficient, even though the number of the probes 1GND for grounding is 50 or 100. Because cost for the components becomes very low, and assembling steps become very simple, remarkable cost reduction can be achieved. Besides, in case of the related art where the contact between the probes for grounding and the metal block is attained by means of the metal tubes, it has been difficult to conduct stable test of the performance, because the metal tubes have various shapes and there are variations in manner of the contact with the probes 1GND for grounding. However, according to the invention, the electrical contact between the probes 1GND for grounding and the ground plate 5 can be reliably obtained, and hence, it is possible to very stably conduct the test of the performance with high reliability.

In the above described embodiment, the ground plate 5 is provided on only one face of the metal block 1 (at the side opposed to the device to be tested). However, manner of inserting the ground plate 5 is not limited to this embodiment, but the insertion can be conducted in various manners, as shown in FIGS. 4B and 4C, for example.

In the structure as shown in FIG. 4B, two sheets of the ground plate 5 are provided on the both faces of the metal block 2. Before inserting the insulating board 31 at the lower side in FIG. 4A, another sheet of the ground plate 5 is inserted. In this case too, since the through hole 51a has a smaller diameter than the outer diameter of the probe 1GND for grounding, the probe 1GND for grounding is unable to be inserted as it is. However, due to the slotted hole 51, the small pieces 51c between the slots will be deformed, and the probe 1GND for grounding can be inserted in a state in contact with the small pieces 51c. Further, the insulating board 31 is inserted and tightly secured with the small screws or the like, whereby the ground plate 5 is firmly brought into contact with the metal block 2, and the respective probes 1 are also fixed. In this structure, although the two sheets of the ground plate 5 are used, the slotted holes 51 and the relief holes 52 can be formed in the same structure and at the same time, as those in the ground plate 5 at the side opposed to the device to be tested. Therefore, it is possible to reliably obtain the electrical contact with the probes 1GND for grounding, without increasing the cost so much.

Further, in the structure as shown in FIG. 4C, the ground plate 5 is inserted between the metal block 2 and the insulating board 31 at the opposite side to the device to be tested. In this case too, the ground plate 5 can be assembled in the same manner, except that the first ground plate 5 in the case as shown in FIG. 4B is not inserted.

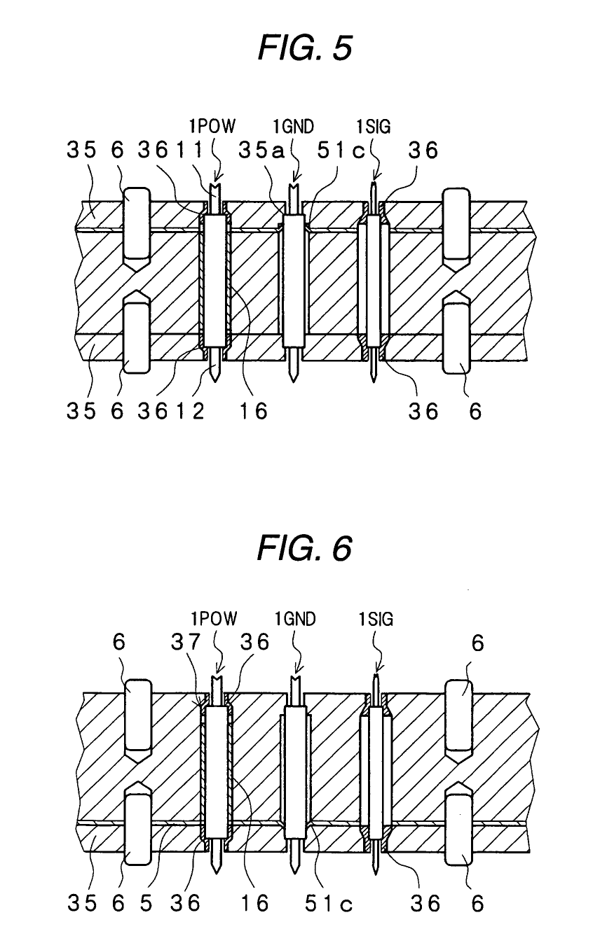

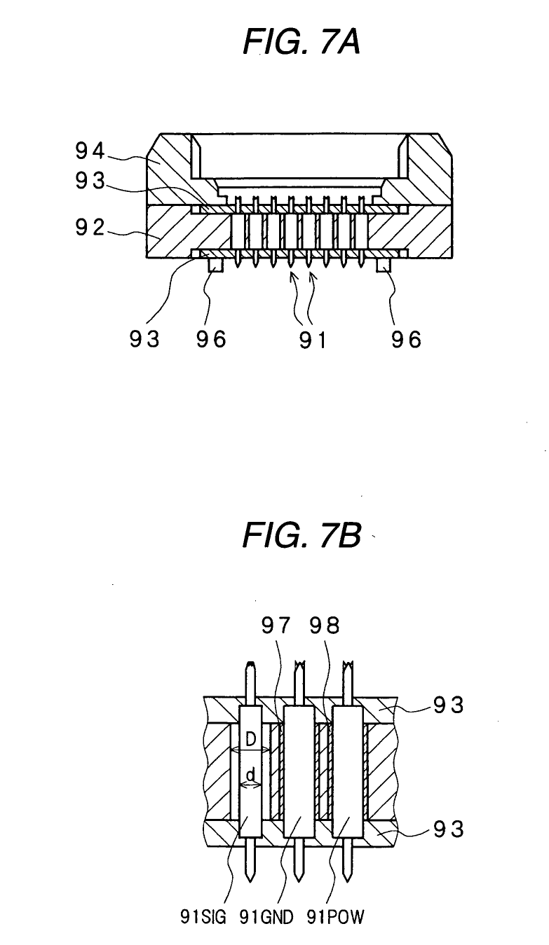

In the above described embodiments, the insulating board 31 is employed as the fixing plate 3 for fixing the probes 1, and the ground plate 5 is interposed between the insulating board 31 and the metal block 2. However, it is also possible to fix the probes 1 with a metal plate. This case is shown in an explanatory sectional view in FIG. 5 which is similar to FIG. 1B (The probe 1POW for power supply is added). Specifically, the embodiment as shown in FIG. 5 is different from the embodiment in FIGS. 1A and 1B in that the fixing plate 3 for fixing the probes 1 is not the insulating board, but a metal plate 35. Because the fixing plate 3 includes the metal plate 35, the probe 1SIG for signals and the probe 1POW for power supply cannot be directly fixed by the metal plate 35. An insulating spacer 36 formed with a dented part having a through hole is inserted into a dented part in the metal plate 35 having a through hole in the same manner, whereby the plungers 11 of the probe 1SIG for signals and the probe 1POW for power supply can be projected from the through holes, while the probe 1SIG for signals and the probe 1POW for power supply are fixed. The fixing means at the opposite side to the device to be tested (the lower side in the drawing) also includes the metal plate 35 and the insulating spacer 36.

On the other hand, a region including the probe 1GND for grounding can be directly brought into contact with the metal plate 35. Therefore, this region is so constructed that the probe 1GND for grounding is directly fixed by a dented part 35a having a through hole which is formed in the metal plate 35, and the plunger 11 is projected from the through hole. In this case too, a relief part for the small pieces 51c is formed in the dented part 35a. Then, the ground plate 5 having the same structure as described above is interposed between the metal plate 35 and the metal block 2, and fixed with the screws or the like which are not shown, while obtaining electrical contact with the metal block 2 together with the metal plate 35. The process for assembling is exactly the same as the process as shown in FIG. 4A. In this manner, the ground plate 5 may be fixed between the metallic materials. Therefore, the metal block 2 may be divided in two, and the ground plate 5 can be inserted between them. In other words, the ground plate 5 may be provided in any place, provided that it can be brought into contact with the probe 1GND for grounding by the slotted hole 51 while maintaining the electrical contact with the metal block 2. Other structures are the same as in the above described embodiments, and the same parts are denoted with the same reference numerals, omitting their descriptions.

FIG. 6 is an explanatory view similar to FIG. 1B, showing still another embodiment of the structure. Specifically, in this embodiment, one of the fixing means for fixing the probe 1 is so constructed that a dented part 37 having a through hole is directly formed in the metal block 2, and the insulating spacer 36 which is formed with the dented part having the substantially same through hole as in the embodiment in FIG. 5 is inserted into the dented part 37, without employing the insulating board and the metal plate. In this structure, the plunger 11 is projected from the through hole, while the probe 1SIG for signals and the probe 1POW for power supply are fixed by the dented part of the insulating spacer 36. In short, this embodiment is the same as the embodiment as shown in FIG. 5, in respect that the probe 1 is fixed by the dented part 37 which is formed in the through hole formed in the metal part, and the insulating spacer 36. In this case too, the probe 1GND for grounding can be directly fixed by the metal block 2 without interposing the insulating spacer 36. In this case, the ground plate 5, which has substantially the same structure as in the embodiment as shown in FIG. 5, is fixed between the metal plate 35 at the lower side, which includes the metal plate 35 and the insulating spacer 36, and the metal block 2. This ground plate has also the same structure as in the embodiment as shown in FIG. 5, except that its position is different. Alternatively, the fixing plate 3 including the insulating board 31 as shown in FIGS. 1A and 1B may be used in place of the metal plate 35, and the ground plate 5 may be interposed between the fixing plate 3 and the metal block 2. Other structures are the same as in the above described embodiments, and the same parts are denoted with the same reference numerals, omitting their descriptions.

According to the socket for test of the invention, it is so constructed that the ground plate in which the slotted holes are formed at the positions for the probes for grounding, and the relief holes having such a size as not interfering with the probes are formed at the positions for the other probes, and that the ground plate is provided so as to come into contact with the metal block. Therefore, there is no necessity of manufacturing the ground tubes which are very difficult to produce and assemble, and inserting such ground tubes into the probes for grounding one by one. Even in case where there are 100 pieces of the probes for grounding, for example, it is possible to reliably connect all the probes for grounding to the metal block which serves as the ground, by providing only one sheet of the ground plate so as to come into contact with the metal block. As the results, different from the ground tubes, electrical connection can be reliably obtained, while remarkable cost reduction can be achieved, and stable test of the performance even for the RF device can be conducted.

This electrical connection between the ground plate and the probe for grounding can be obtained in such a way that, the small pieces are formed between a plurality of slots of the slotted hole, where each slotted hole includes the through hole having the smaller diameter than the probe and each of the slots radially is extended from the through hole, and the small pieces are bent by insertion of the probe for grounding, and pressed to be brought into contact with the probe for grounding by their resiliency. For this reason, the ground plate must be formed of resilient and easily deformable material, because it must be bent by the very thin probe having the outer diameter of about 0.3 mm. Therefore, resilient material such as phosphor bronze, stainless steel having a thickness of about 0.02 to 0.05 mm must be employed as the ground plate. Moreover, the length and the number of the slots should be set so as to be optimum according to the pitch of the electrode terminals of the device to be tested and so on. Specifically, in case where the pitch of the electrode terminals of the device to be tested is large, an interval between the adjacent through holes is also large, and the long slots can be used. Therefore, even though the number of the slots is small, the small pieces can be sufficiently deformed to be brought into contact with the probe for grounding. On the other hand, in case where the pitch of the probes is small, the deep slots cannot be made. In this case, by increasing the number of the slots to make the small pieces between the slots easily deformable, the optimal contact with the probe for grounding can be obtained, without deforming the probe.

What is claimed is:

1. A socket for test, comprising:
a support block, having a first face and a second face different from the first face, and formed with a plurality of through holes;
a plurality of probes, provided in the through holes, and electrically connected to terminals of a device to be tested which is provided on a side of the first face and to terminals connected to a testing apparatus which is provided on a side of the second face, the probes including a first probe for grounding and a second probe different from the first probe; and
a first plate member, formed with a first hole corresponding to the first probe and having a smaller diameter than a diameter of the first probe, slots radially extended from the first hole, and a second hole corresponding to the second probe and having a larger diameter than a diameter of the second probe, the first plate member being in electrical contact with the support block.

2. The socket as claimed in claim 1, wherein
the support block is comprised of metal.

3. The socket as claimed in claim 1, wherein
each of the probes includes a spring member, and
one end of each probe can be projected to at least the side of the first face of the support block.

4. The socket as claimed in claim 1, further comprising
a second plate member, provided on at least one of the first face and the second face of the support block, and comprised of one of insulating material and metallic material.

5. The socket as claimed in claim 4, wherein
the first plate member is arranged between the second plate member and the support block.

6. The socket as claimed in claim 1, wherein
the first plate member includes a metal plate having a thickness of 0.02 mm to 0.05 mm.

7. The socket as claimed in claim 1, wherein
the number of the slots is three to sixteen.
